(19) United States
(12) Patent Application Publication
(10) Pub. No.: US 2021/0340689 A1
(43) Pub. Date: Nov. 4, 2021

(54) CRUCIBLE AND CRYSTAL GROWTH EQUIPMENT

(71) Applicant: TDK CORPORATION, Tokyo (JP)

(72) Inventor: Tatsuya TERUI, Tokyo (JP)

(73) Assignee: TDK CORPORATION, Tokyo (JP)

(21) Appl. No.: 17/240,349

(22) Filed: Apr. 26, 2021

(30) Foreign Application Priority Data
Apr. 30, 2020 (JP) 2020-080505

(51) Int. Cl. C30B 15/10; C30B 35/00

(52) U.S. Cl. CPC C30B 15/10; C30B 35/002

(57) ABSTRACT

Provided is a crucible capable of improving uniformity of a temperature distribution of a melt drawn by a seed crystal and obtaining a crystal having a more uniform composition, and a crystal growth equipment including the crucible. The crucible includes a melt storage portion 24 that stores a melt that is a raw material of a crystal, and a die unit 34 that controls a shape of the crystal. The die portion 34 includes a die flow path 36 through which the melt 30 is passed from a storage portion outlet 32 provided on a bottom surface of the melt storage portion 24 toward a die outlet 38 provided on an end surface of the die portion 34. The die flow path 36 includes a narrow portion 36a1 whose flow path cross-sectional area is smaller than an opening area of the die outlet 38.

### BACKGROUND OF THE INVENTION

### Field of the Invention

The present invention relates to a crucible used for, for example, a micro-pulling down method (hereinafter referred to as a ≅PD method), and a crystal growth equipment including the crucible.

### Description of the Related Art

In a ≅PD method, a melt of a single crystal material flowing out from a pore of a crucible comes into contact with a seed crystal arranged below the pore, and a desired single crystal grows on the seed crystal as the melt cools. By pulling down a seed crystal holder that holds the seed crystal according to a growth rate of the single crystal, the single crystal can be grown in a pulling down direction of the seed crystal.

As the crucible used in the ≅PD method, for example, a crucible shown in Patent Literature 1 (J P-A-2005-35861) is known. In the crucible shown in Patent Literature 1, by devising a shape of an outer bottom surface of the crucible, increasing the number of pores, providing an after-heater, and the like, attempts have been made to achieve uniformity of a temperature distribution of the melt drawn by the seed crystal and to obtain a crystal having a uniform composition.

However, it has become clear that it is difficult to sufficiently achieve the uniformity of the temperature distribution of the melt drawn by the seed crystal with a configuration of the crucible in the related art.

### SUMMARY OF THE INVENTION

The present invention is made in view of such a circumstance and an object thereof is to provide a crucible capable of improving uniformity of a temperature distribution of a melt drawn by a seed crystal and obtaining a crystal having a more uniform composition, and a crystal growth equipment including the crucible.

In order to achieve the above object, a crucible according to the present invention is

a crucible including a melt storage portion for storing a melt of a raw material of a crystal; and a die portion defining a shape of the crystal, in which

the die portion includes a die flow path through which the melt is passed from a storage portion outlet provided on a bottom surface of the melt storage portion toward a die outlet provided on an end surface of the die portion, and

the die flow path includes a narrow portion having a flow path cross-sectional area smaller than an opening area of the die outlet.

As a result of earnest investigation on the uniformity of the temperature distribution, the present inventor has found that the uniformity of the temperature distribution of the melt drawn by the seed crystal (particularly uniformity of the temperature distribution at a solid-liquid interface along a plane perpendicular to a drawing direction of the melt) can be achieved by providing the narrow portion in a middle of the die flow path when passing the melt from the melt storage portion to the die flow path of the crucible. Thus, the present invention has been completed. According to experiments of the present inventor, it has been confirmed that a crystal having a more uniform composition (particularly a uniform composition along a plane perpendicular to a drawing direction of the crystal) can be obtained by using the crucible.

Preferably, the die flow path includes a divergent portion whose flow path cross-sectional area increases from the narrow portion toward the die outlet along a pulling down direction of the melt With such a configuration, the uniformity of the temperature distribution of the melt drawn by the seed crystal and the uniformity of the composition of the obtained crystal are improved.

The die flow path may include an introduction portion whose inlet is a connected to the storage portion outlet and a flow path main body portion communicating with the introduction portion, and it is preferable that an outlet of the flow path main body portion is connected to the die outlet. The die flow path may not include the introduction portion and may include only the flow path main body portion, but it is preferable that the die flow path includes the introduction portion.

The introduction portion may have a flow path cross-sectional area that changes along a flow direction, but preferably, the introduction includes is a straight body portion having a substantially constant flow path cross-sectional area along the flow direction of the melt. The term “substantially constant” means that the cross-sectional area may be changed to some extent, and the cross-sectional area is less changed than the divergent portion formed at the flow path main body portion. In the introduction portion, the flow path may be slightly expanded or slightly narrowed from the storage portion outlet toward the flow path main body portion.

Preferably, the introduction portion (including the storage portion outlet, a middle of the introduction portion, or a boundary between the introduction portion and the flow path main body portion) includes the narrow portion. When the introduction portion is a straight body portion, the narrow portion is formed at a middle of the straight body portion, the storage portion outlet, or the boundary between the introduction portion and the flow path main body portion. Since the narrow portion is formed at the introduction portion, it becomes easy to adjust a flow rate of the melt stored in the storage portion passing through the die flow path. The melt can be drawn from the die outlet at a stable speed, and the uniformity of the composition of the crystal (uniformity in the drawing direction) is improved.

The flow path main body portion may includes the narrow portion. When the narrow portion is formed at the flow path main body portion, a divergent portion whose flow path cross-sectional area increases from the narrow portion toward the die outlet is formed. An intermediate-expanded portion having a cross-sectional area larger than that of the introduction portion and the narrow portion may be formed between the narrow portion formed at the flow path main body portion and the introduction portion.

Preferably, a ratio (S2/S1) of the opening area (S2) of the die outlet to the flow path cross-sectional area (S1) of the narrow portion is 3 to 3000. Within such a range, the uniformity of the temperature distribution of the melt drawn by the seed crystal and the uniformity of the composition of the obtained crystal are improved.

Preferably, a flat end peripheral surface that is substantially perpendicular to the drawing direction of the melt is provided at the end surface of the die portion around the die outlet With such a configuration, an outer peripheral surface shape of the crystal obtained by using the crucible can be easily controlled.

A ratio (S2/(S2+S3)) of the opening area (S2) of the die outlet to a sum of the opening area (S2) of the die outlet and an area (S3) of the end peripheral surface is preferably 0.1 to 0.95, and more preferably 0.50 to 0.90. With such a configuration, the uniformity of the temperature distribution of the melt drawn by the seed crystal and the uniformity of the composition of the obtained crystal are further improved.

The crucible is made of a heat-resistant material, such as iridium, rhenium, molybdenum, tantalum, tungsten, platinum, or an alloy thereof, or carbon.

A crystal growth equipment according to the present invention includes any one of the above crucibles.

### BRIEF DESCRIPTION OF THE DRAWINGS

FIG. 1 is a schematic cross-sectional view of a crystal growth equipment according to an embodiment of the present invention.

FIG. 2A is an enlarged cross-sectional view of a part II of the crystal growth equipment shown in FIG. 1.

FIG. 2A1 is an enlarged cross-sectional view of a die portion shown in FIG. 2A.

FIG. 2B is an enlarged cross-sectional view of a crystal growth equipment according to another embodiment of the present invention.

FIG. 2C is an enlarged cross-sectional view of a crystal growth equipment according to still another embodiment of the present invention.

FIG. 2D is an enlarged view of a crystal growth equipment according to a fourth embodiment, which is another modification of FIG. 2A.

FIG. 3A is an arrow view of the die portion shown in FIG. 2A along a line III-III.

FIG. 3B is a schematic view showing a temperature distribution of a melt immediately after being drawn from the die portion using the crystal growth equipment according to Examples of the present invention.

FIG. 3C is a schematic view showing a concentration distribution of Ce in a cross section of Ce:YAG produced by using the crystal growth equipment according to Examples of the present invention.

FIG. 4 is an enlarged cross-sectional view of a die portion of a crystal growth equipment in the related art used in Comparative Example of the present invention.

FIG. 5A is an arrow view along a line V-V shown in FIG. 4.

FIG. 5B is a schematic view showing a temperature distribution of a melt immediately after being drawn from the die portion using the crystal growth equipment according to Comparative Example.

FIG. 5C is a schematic view showing a concentration distribution of Ce in a cross section of Ce:YAG produced by using the crystal growth equipment according to Comparative Example.

### DETAILED DESCRIPTION OF THE PREFERRED EMBODIMENTS

Hereinafter, the present invention will be described based on embodiments shown in the drawings.

### First Embodiment

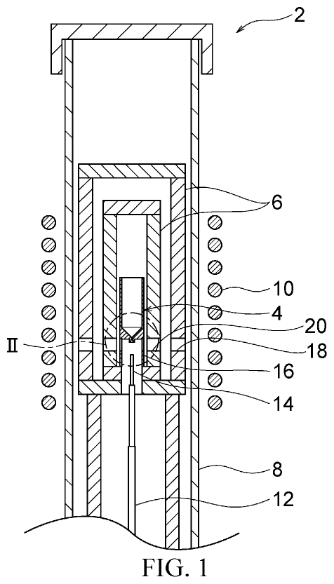

As shown in FIG. 1, a crystal growth equipment 2 according to the present embodiment includes a crucible 4 and refractory furnaces 6. The crucible 4 will be described later. The refractory furnaces 6 cover a periphery of the crucible 4 doubly. The refractory furnaces 6 are formed with observation windows 18, 20 for observing a pulling down state of a melt from the crucible 4.

The refractory furnaces 6 are further covered with an outer casing 8, and a main heater 10 for heating the entire crucible 4 is provided on an outer periphery of the outer casing 8. In the present embodiment, the outer casing is formed by, for example, a quartz tube, and an induction heating coil 10 is used as the main heater 10. A seed crystal 14 held by a seed crystal holding jig 12 is arranged below the crucible 4. As the seed crystal 14, a crystal of the same or the same type as a crystal to be produced is used. For example, if the crystal to be produced is a Ce-doped YAG crystal, a YAG single crystal containing no additives is used.

A material of the seed crystal holding jig 12 is not particularly limited, but the seed crystal holding jig 12 is preferably made of dense alumina or the like, which has little influence at an operating temperature of around 1900° C. A shape and a size of the seed crystal holding jig 12 are not particularly limited, but a rod shape having a diameter so that the jig does not come into contact with the refractory furnace 6 is preferred.

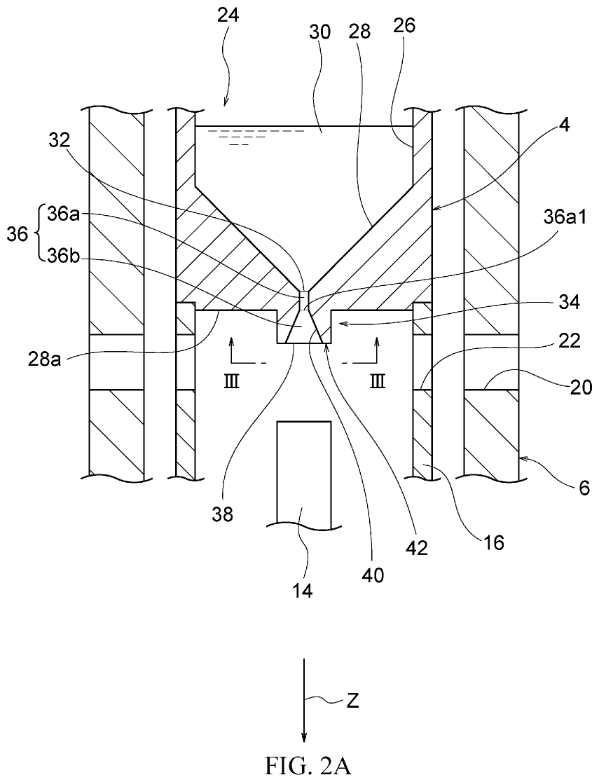

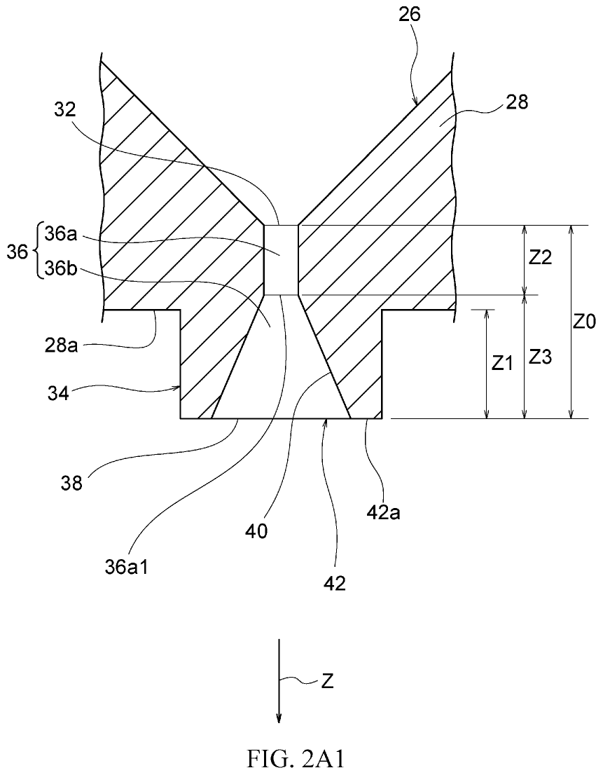

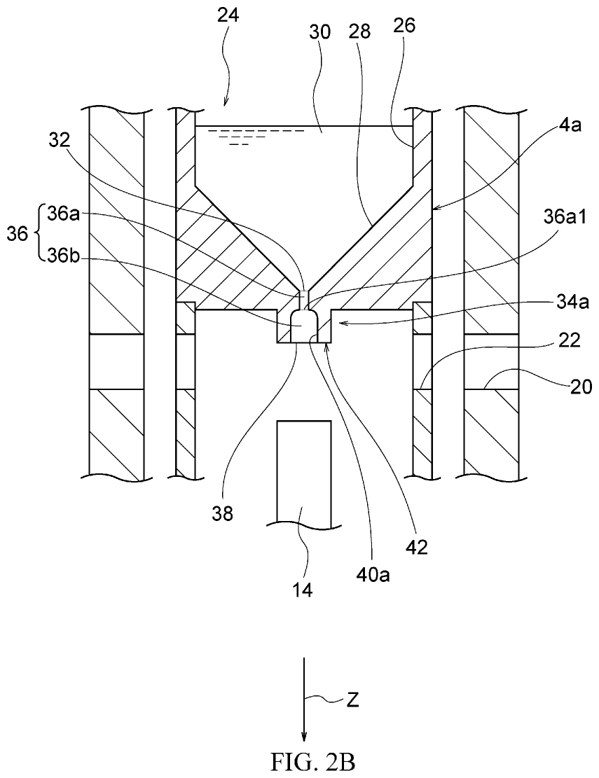

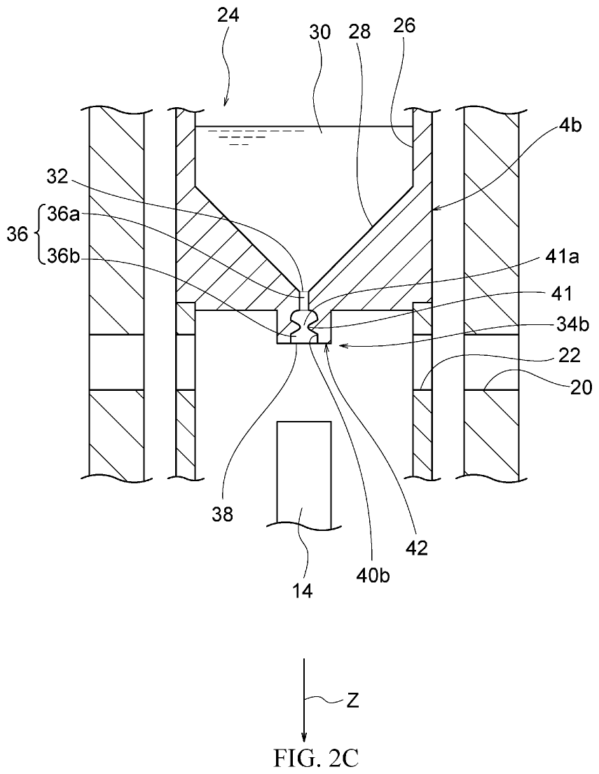

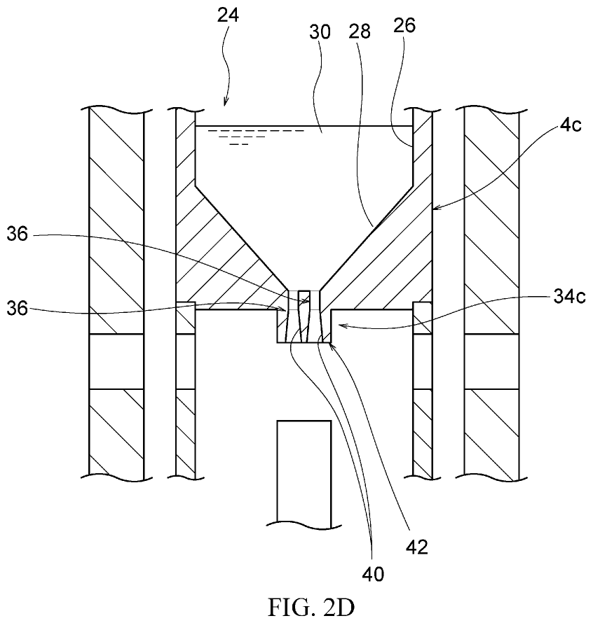

As shown in FIG. 2A, a cylindrical after-heater 16 is installed on an outer periphery of a lower end of the crucible 4. The after-heater 16 is formed with an observation window 22 at the same position as the observation window 20 of the refractory furnace 6. The after-heater 16 is used by being connected to the crucible 4, and is arranged so that a die outlet 38 of a die portion 34 of the crucible 4 is located in an inner space of the cylindrical after-heater 16, so as to heat the melt drawn from the die portion 34 and the die outlet 38. The after-heater 16 is made of, for example, the same material as the crucible 4 (it does not have to be the same). When the after-heater 16 is induced and heated by the high frequency coil 10 similar to the crucible 4, radiant heat is generated from an outer surface of the after-heater 16, and an inside of the after-heater 16 can be heated.

Although not shown, the crystal growth equipment 2 includes a decompression unit for decompressing an inside of the refractory furnace 6, a pressure measuring unit for monitoring the decompression, a temperature measuring unit for measuring a temperature of the refractory furnace 6, and a gas supply unit for supplying an inert gas to the inside of the refractory furnace 6.

A material of the crucible 4 is preferably iridium, rhenium, molybdenum, tantalum, tungsten, platinum, or an alloy thereof for reasons such as a high melting point of the crystal. The crucible 4 may be made of carbon. It is more preferable to use iridium (Ir) as the material of the crucible 4 in order to prevent foreign substances from being mixed into the crystal due to oxidation of the material of the crucible 4.

When a substance having a melting point of 1500° C. or lower is targeted, Pt can be used as the material of the crucible 4. When Pt is used as the material of the crucible 4, crystal growth in atmosphere is possible. When a substance having a high melting point exceeding 1500° C. is targeted, Ir or the like is used as the material of the crucible 4, and therefore the crystal growth is preferably carried out in an inert gas atmosphere such as Ar. A material of the refractory furnace 6 is not particularly limited, but alumina is preferred from viewpoints of heat retention, operating temperature, and prevention of impurities from being mixed into the crystal.

Next, the crucible 4 used in the crystal growth equipment 2 according to the present embodiment will be described in detail. A s shown in FIG. 2A, the crucible 4 according to the present embodiment incudes a melt storage portion 24 for storing a melt 30, which is a raw material of the crystal, and the die portion 34 for controlling a shape of the crystal, and the melt storage portion 24 and the die portion 34 are integrally formed. When the crucible 4 is large, a plurality of members may be joined in a middle of a longitudinal direction of the melt storage unit 24 to configure the crucible 4.

In the present embodiment, the crucible 4 is used for the ≅PD method. The die portion 34 is located below the melt storage portion 24 in a vertical direction, and the melt 30 stored in the melt storage portion 24 is drawn from the die outlet 38, which is formed in a lower end surface 42 of the die portion 34, by the seed crystal 14 downward in the vertical direction.

The melt storage portion 24 includes a cylindrical side wall 26 and a bottom wall 28 continuously formed with the side wall 26. A certain amount of the melt 30 can be stored in the melt storage portion 24 by an inner surface of the side wall 26 and an inner surface of the bottom wall 28. A storage portion outlet 32 is formed at a substantially central portion of the bottom wall 28. The storage portion outlet 32 communicates with a die flow path 36 formed at the die portion 34. The die flow path 36 will be described later.

The inner surface of the bottom wall 28 is a reverse-tapered inclined surface whose inner diameter decreases downward, and the melt 30 in the melt storage portion 24 can easily flow toward the storage portion outlet 32. An outer surface of the bottom wall 28 is preferably flush with an outer surface of the side wall 26, and is more preferably flush with the outer surface of the after-heater 16. A lower surface 28a of the bottom wall 28 is a flat plane substantially perpendicular to a flow direction (also referred to as a drawing direction or a pulling down direction) Z of the melt 30, and the after-heater 16 is connected to an outer peripheral portion thereof.

At least a part of the die portion 34 is formed to protrude downward at a substantially central portion of the lower surface 28a of the bottom wall 28. As shown in FIG. 2A 1, the lower end surface 42 of the die portion 34 protrudes from the lower surface 28a of the bottom wall 28 at a predetermined distance Z1. The die outlet 38 formed at a substantially central portion of the lower end surface 42 of the die portion 34 and the storage portion outlet 32 formed at the substantially central portion of the bottom wall 28 are connected via the die flow path 36 formed at the die portion 34.

Into the present embodiment, the die flow path 36 includes an introduction portion 36a whose inlet is the storage portion outlet 32, and a flow path main body portion 36b communicating with the introduction portion 36a, in which an outlet of the flow path main body portion 36b is the die outlet 38. The die flow path 36 may not include the introduction portion 36a, and may have only the flow path main body portion 36b, but it is preferable that the die flow path 36 includes the introduction portion 36a.

In the present embodiment, the introduction portion 36a may have a flow path cross-sectional area (a cross-sectional area perpendicular to the flow direction) that changes along the flow direction, but preferably, the introduction portion 36a is a straight body portion having a substantially constant flow path cross-sectional area along the drawing direction Z. In the present embodiment, the term “substantially constant” means that the cross-sectional area may be changed to some extent, but the cross-sectional area is less changed than a divergent portion 40 formed at the flow path main body portion 36b. A change in the cross-sectional area is preferably within approximately ĕ10%, and more preferably within ĕ5%. In the introduction portion 36a, the flow path may be slightly expanded or slightly narrowed from the storage portion outlet 32 toward the flow path main body portion 36b.

In the present embodiment, a narrow portion 36a1 is formed at the introduction portion 36a (including the storage portion outlet 32, a middle of the introduction portion 36a, or a boundary between the introduction portion 36a and the flow path main body portion 36b). When the introduction portion 36a is a straight body portion, the narrow portion 36a1 is formed at a middle of the straight body portion, the storage portion outlet 32, or the boundary between the introduction portion 36a and the flow path main body portion 36b at a portion where the flow path cross-sectional area is minimum Since the narrow portion 36a1 is formed at the introduction portion 36a, it becomes easy to adjust a flow rate of the melt stored in the storage portion 24 passing through the die flow path 36, the melt can be drawn from the die outlet 38 at a stable speed, and uniformity of a composition of the crystal (particularly uniformity in the drawing direction) is improved.

According to the present embodiment, the narrow portion 36a1 is a portion in the die flow path 36 whose flow path cross-sectional area is smaller than an opening area of the die outlet 38, and having a flow path cross-sectional area equal to or smaller than the opening area on an upstream side thereof and smaller than the opening area on a downstream side thereof along the drawing direction Z. When two or more narrow portions 36a1 are present along the die flow path 36, the narrow portion closest to the die outlet 38 is the narrow portion 36a1 according to the present embodiment.

For example, in the present embodiment, as shown in FIG. 2A 1, since the introduction portion 36a is the straight body portion, the narrow portion 36a1 is formed at the middle of the introduction portion 36a, the storage portion outlet 32, or the boundary between the introduction portion 36a and the flow path main body portion 36b.

In the present embodiment, the flow path main body portion 36b includes the divergent portion 40 whose flow path cross-sectional area increases from the narrow portion 36a1 toward the die outlet 38 along the pulling down direction Z. In the present embodiment, the divergent portion 40 is formed in a tapered shape in which the flow path cross-sectional area gradually increases from the narrow portion 36a1 of the introduction portion 36a toward the die outlet 38.

A length Z2 of the introduction portion 36a along the drawing direction Z is preferably 0 mm to 5 mm, and more preferably 0.5 mm to 2 mm. Since the narrow portion 36a as the straight body portion is formed, it becomes easy to adjust the flow rate of the melt stored in the storage portion 24 passing through the die flow path 36, the melt can be drawn from the die outlet 38 at a stable speed, and the uniformity of the composition of the crystal (uniformity in the drawing direction) is improved.

A length Z3 of the flow path main body portion 36b along the drawing direction Z is determined by, for example, a relation with a total length Z0 (=Z2+Z3) of the die flow path 36, and a ratio (Z3/Z0) is preferably 0.1 to 1, and more preferably 0.2 to 0.8. Alternatively, the length Z3 of the flow path main body portion 36b along the drawing direction Z is preferably 1 mm to 5 mm, and more preferably 1.5 mm to 2.5 mm.

The length Z3 of the flow path main body portion 36b along the drawing direction Z may be the same as or different from the distance Z1 from the lower surface 28a of the bottom wall 28 to the lower end surface 42 of the die portion 34. The distance Z1 from the lower surface 28a of the bottom wall 28 to the lower end surface 42 of the die portion 34 along the drawing direction Z is preferably determined so that the melt drawn from the die outlet 38 does not adhere to the lower surface 28a of the bottom wall 28, and is, for example 1 mm to 2 mm.

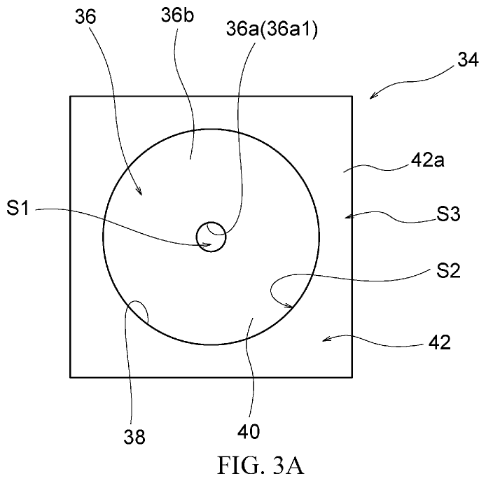

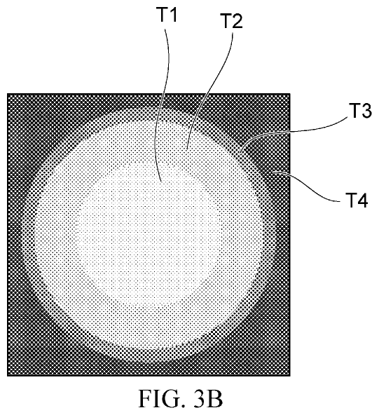

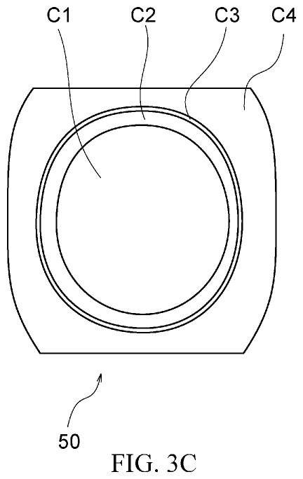

As shown in FIG. 3A, on the lower end surface 42 of the die portion 34, a flat end peripheral surface 42a that is substantially perpendicular to the drawing direction Z (see FIG. 2A) is formed around the die outlet 38. The end peripheral surface 42a is formed between an outer shape of the lower end surface 42 of the die portion 34 and an outer shape of the die outlet 38.

A ratio (S2/(S2+S3)) of an opening area S2 (area perpendicular to the drawing direction Z) of the die outlet 38 to a sum of an area S3 (area perpendicular to the drawing direction Z) of the end peripheral surface 42a and the S2 is preferably 0.10 to 0.95, and more preferably 0.5 to 0.95. A ratio (S2/S1) of the opening area (S2) of the die outlet 38 to a flow path cross-sectional area (S1) of the narrow portion 36a1 is preferably 3 to 3000, and more preferably 10 to 2000. In the present embodiment, the flow path cross-sectional area (S1) of the narrow portion 36a1 is the same as the flow path cross-sectional area of the introduction portion 36a, which is the straight body portion, and the area (S1) is determined so that a speed of the melt drawn from the die outlet 38 of the die flow path 36 and the like is constant, and is preferably 0.008 mm² to 0.2 mm².

In the present embodiment, the outer shape of the lower end surface 42 of the die portion 34 is rectangular according to a cross-sectional (cross section perpendicular to the pulling down direction Z) shape of an obtained crystal body, and a shape of the die outlet 38 is circular but is not limited thereto. For example, the outer shape of the lower end surface 42 of the die portion 34 may also be a circle, a polygon, an ellipse, or any other shape according to the cross-sectional shape of the obtained crystal body. A cross-sectional shape of the die outlet 38 is also not limited to a circle, but may be a polygon, an ellipse, or any other shape. Cross-sectional shapes of the introduction portion 36a and the flow path main body portion 36b are also not limited to a circle, but may be a polygon, an ellipse, or any other shape. The cross-sectional shape of the introduction portion 36a and the cross-sectional shape of the flow path main body portion 36b may be the same or different, but are preferably the same.

The crystal growth equipment 2 including the crucible 4 according to the present embodiment shown in FIG. 1 is preferably used in the ≅PD method or the like. The raw material charged into the melt storage portion 24 of the crucible 4 is heated by the main heater 10 or the like to become the melt 30 shown in FIG. 2A, and is drawn by the seed crystal 14 from the die outlet 38 through the die flow path 36 of the die portion 34, and by pulling down the seed crystal 14, the crystal is grown to obtain the crystal body.

Next, a method for producing a crystal using the crystal growth equipment 2 of the present embodiment will be briefly described. In the crystal growth equipment 2 of the present embodiment, first, the raw material of the crystal body to be obtained is charged into the melt storage portion 24 of the crucible 4, and the main heater 10 is activated to heat the melt storage portion 24. The melt storage portion 24 is heated so that the raw material melts in the melt storage portion 24 to become the melt 30, which flows from the storage portion outlet 32 of the die portion 34 to the die flow path 36. The melt 30 passes through the introduction portion 36a and the flow path main body portion 36b and then comes into contact with an upper end of the seed crystal 14 at the die outlet 38.

Around this time, the after-heater 16 is also activated to heat the vicinity of the die portion 34. By using the crucible 4 of the present embodiment, the temperature of the melt pulled down by the seed crystal 14 via the die outlet 38 becomes substantially uniform, particularly in a plane perpendicular to the pulling down direction Z.

By using the crucible 4 according to the present embodiment, a concentration distribution of a composition (containing an activator) in the crystal body grown from the die outlet 38 is substantially uniform particularly in the plane perpendicular to the pulling down direction Z, and is also substantially uniform in a plane parallel to the pulling down direction Z. When YAG:Ce is to be produced for example, by using the apparatus 2 of the present embodiment, a crystal body YAG:Ce in which an activator such as Ce is uniformly dispersed can be obtained.

That is, in the present embodiment, the melt 30 from the melt storage portion 24 of the crucible 4 passes through the narrow portion 36a1 provided in the introduction portion 36a of the die flow path 36, then passes through the divergent portion 40 from the narrow portion 36a1 toward the die outlet 38, and is pulled down from the die outlet 38 together with the seed crystal 14. With such a configuration, the uniformity of the temperature distribution of the melt drawn by the seed crystal (particularly the uniformity along the plane perpendicular to the drawing direction of the melt) and the uniformity of the composition of the obtained crystal are improved.

In the present embodiment, since the narrow portion 36a1 is formed at the introduction portion 36a, it becomes easy to adjust the flow rate of the melt stored in the storage portion 24 passing through the die flow path 36. The melt can be drawn from the die outlet 38 and then crystallized at a stable speed, and the uniformity of the composition of the crystal (particularly uniformity in the drawing direction) is improved.

In the present embodiment, since the flat end peripheral surface 42a that is substantially perpendicular to the drawing direction Z of the melt 30 is provided at the lower end surface 42 of the die portion 36 around the die outlet 38, an outer peripheral surface shape of the crystal body obtained by using the crucible 4 can be easily controlled. Furthermore, in the present embodiment, a ratio (S2/S3) of the opening area (S2) of the die outlet 38 to the area (S3) of the end peripheral surface 42a is set within a predetermined range, and the ratio (S2/S1) of the opening area (S2) of the die outlet 38 to the flow path cross-sectional area (S1) of the narrow portion 36a1 is also set within a predetermined range. With such configurations, the uniformity of the temperature distribution of the melt drawn by the seed crystal and the uniformity of the composition of the obtained crystal are further improved.

### Second Embodiment

As shown in FIG. 2B, in a crystal growth equipment according to the present embodiment, only a configuration of a die portion 34a of a crucible 4a is different from that of the first embodiment. Some of the same portions will be omitted, and different portions will be described in detail below. Portions not described below are the same as in the description of the first embodiment.

In the die flow path 36 of the crucible 4a according to the present embodiment, a shape of a divergent portion 40a, whose flow path cross-sectional area increases from a narrow portion 36a1 formed at an introduction portion 36a toward the die outlet 38, is not a tapered shape in which the cross-sectional area increases linearly, but a shape in which the cross-sectional area expands in a concave curve. The divergent portion 40a of the present embodiment may have a straight body portion having substantially the same cross-sectional area along the pulling down direction Z near the die outlet 38, but it is preferable that the straight body portion is short. In the present embodiment, the shape of the divergent portion 40a may be a shape in which the cross-sectional area increases in a convex curve or another curve, instead of the shape in which the cross-sectional area increases in a concave curve.

### Third Embodiment

As shown in FIG. 2C, in a crystal growth equipment according to the present embodiment, only a configuration of a die portion 34b of a crucible 4b is different from that of the first or second embodiment Some of the same portions will be omitted, and different portions will be described in detail below. Portions not described below are the same as in the description of the first or second embodiment.

A narrow portion 41a is formed at the flow path main body portion 36b in the die flow path 36 of the crucible 4b according to the present embodiment. When the narrow portion 41a is formed at the flow path main body portion 36b, a divergent portion 40b whose flow path cross-sectional area increases from the narrow portion 41a toward the die outlet 38 is formed. In the present embodiment, an intermediate-expanded portion having a larger cross-sectional area than the introduction portion 36a and the narrow portion 41a may be formed between the narrow portion 41a formed at the flow path main body portion 36b and the introduction portion 36a.

The narrow portion 41a of the present embodiment corresponds to the narrow portion 36a1 of the first or second embodiment described above. The flow path cross-sectional area S1 thereof has the same relation with the opening area S2 of the die outlet 38. The distance Z3 from the narrow portion 41a to the die outlet 38 has the same relation as in the first or second embodiment described above.

An inner diameter of the introduction portion 36a of the present embodiment is preferably equal to or greater than an inner diameter of the narrow portion 41a, but may be smaller as long as the melt 30 can pass through. In the present embodiment, the introduction portion 36a may also be formed with a portion having a flow path cross-sectional area smaller than the opening area of the die outlet 38. However, in the present embodiment, the portion that greatly contributes to the uniformity of the temperature distribution of the melt drawn by the seed crystal 14 is the narrow portion 41a that is a starting point of the divergent portion 40b toward the die outlet 38.

### Forth Embodiment

As shown in FIG. 2D, in a crystal growth equipment according to the present embodiment, only a configuration of a die portion 34c of a crucible 4c is different from those in the first to third embodiments. Some of the same portions will be omitted, and different portions will be described in detail below. Portions not described below are the same as in the descriptions of the first to third embodiments.

In the die portion 34 of the crucible 4c according to the present embodiment, a plurality of (for example, 2 to 8) die flow paths 36 are formed. Each die flow path 36 has the same configuration with that of any of the first to third embodiments. It is preferable that the plurality of die flow paths 36 (for example, 2 to 8) have the same configuration, but may be different. For example, one of the plurality of die flow paths 36 has the same configuration as the die flow path 36 of the first embodiment, and the others may have the same configuration with the die flow path 36 of the second or third embodiment.

The present invention is not limited to the above embodiments, and various modifications can be made within a scope of the present invention. For example, the crystal produced by using the crucible and the crystal growth equipment of the present invention is not limited to a single crystal YAG or LuAG doped with an M element, and single crystals such as Al₂O₃ (sapphire), GAGG (Gd₃Al₂Ga₃O₁₂), GGG (Gd₃Ga₅O₁₂), and GPS (Gd₂Si₂O₇) are also exemplified. The crystal is not limited to a single crystal, and may be a co-crystal such as YAG-Al₂O₃ or LuAG-Al₂O₃.

### EXAMPLES

Hereinafter, the present invention will be described based on more detailed Examples, but the present invention is not limited to these Examples.

### Example 1

Using the crystal growth equipment 2 shown in FIG. 1, a phosphor made of a single crystal Ce:YAG (YAG doped with Ce) was produced. An inner diameter of the introduction portion 36a as the straight body portion shown in FIG. 2A was 0.4 mm, and an inner diameter of the die outlet 38 was 4 mm. The length Z2 of the introduction portion 36a shown in FIG. 2A 1 was 0.5 mm, and the length Z3 of the flow path main body portion 36b was 2 mm.

FIG. 3B shows a temperature distribution of the melt (near the solid-liquid interface) immediately after the melt is drawn from the die outlet 38 of the die portion 34 using the crystal growth equipment 2 according to Example 1. T1, T2, T3, and T4 each represent a temperature of an indicated region. The temperature is lowest in T1 and gradually increases from T2 to T3 to T4. For example, the temperature T1 was 1945° C. to 1953° C.; the temperature T2 was 1953° C. to 1961° C.; the temperature T3 was 1965° C. to 1973° C.; and the temperature T4 was 1973° C. or higher. The temperature distribution was measured by simulation analysis.

As can be seen by comparing FIG. 3A with FIG. 3B, in a portion corresponding to the die outlet 38, an area of the portion where the uniform temperatures T1 and T2 are obtained is large. FIG. 3C shows a concentration distribution of Ce in a cross section of Ce:YAG produced by the crystal growth equipment 2 of Example 1. In FIG. 3C, C1, C2, C3, and C4 represent concentrations of Ce (¼ 100/(+ [symbol] ), in which an atomic % of Y is defined as [symbol] , and an atomic % of Ce is defined as in the indicated regions. The concentration is lowest in C1 and gradually increases from C2 to C3 to C4. In Example 1, the concentration C1 was 0.94 atomic % to 1.07 (1.00 ĕ 0.07) atomic %; the concentration C2 was 1.08 atomic % to 1.22 atomic %; the concentration C3 was 1.23 atomic % to 1.37 atomic %; and the concentration C4 was 1.38 atomic % or more. The concentration distribution was measured by LA (laser ablation)-ICP mapping.

As shown in FIG. 3C, the concentration of Ce in the cross section of the grown Ce:YAG crystal was distributed so as to correspond to the temperature distribution shown in FIG. 3B. Corresponding to the outlet 38 of the die flow path 36 shown in FIG. 3A, an area of a region in which the concentration of Ce was uniform with C1 was large, and a size (occupied area) of a largest uniform concentration region was approximately 43.4% of a total cross-sectional area of the obtained crystal body. The region in which the concentration of Ce is uniform with C1 is located in a central portion of the crystal body, and is close to a circle. Therefore, a crystal body having a relatively large cross-sectional area and a uniform concentration can be obtained.

### Comparative Example 1

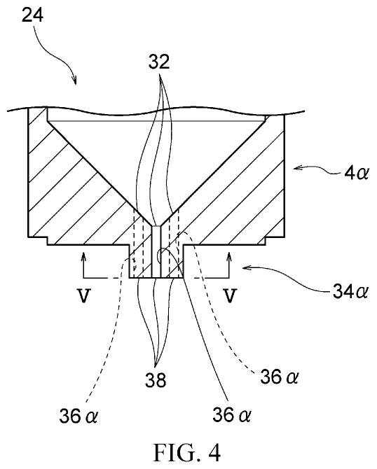

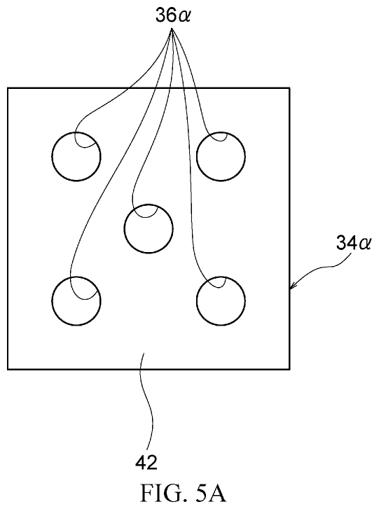

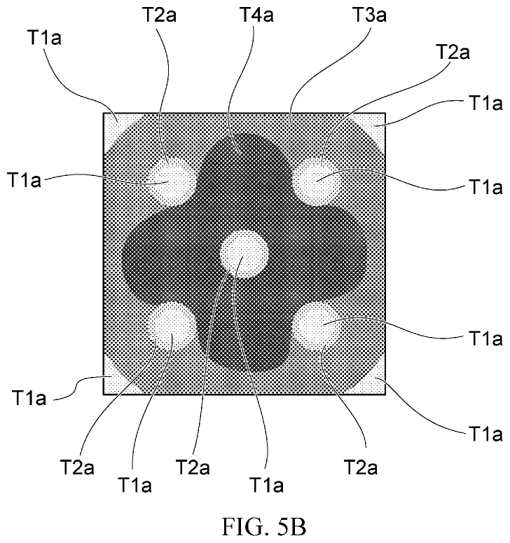

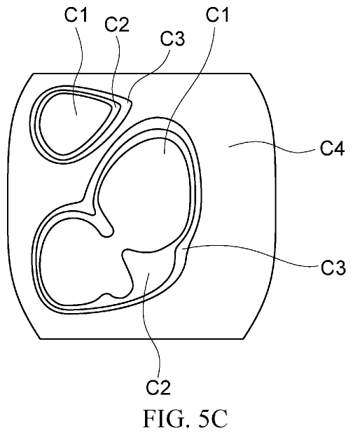

A phosphor made of a single crystal Ce:YAG was produced in the same manner as in Example 1 except for that as shown below. The fluophor made of the single crystal Ce:YAG was produced in the same manner as in Example 1 using the same crystal growth equipment as in Example 1 except that a crucible 4 in the related art shown in FIGS. 4 and 5A was used.

As shown in FIG. 4, the crucible 4 used in Comparative Example 1 includes the melt storage portion 24 and a die portion 34. Five storage portion outlets 32 are formed at the central portion of the bottom wall 26 of the melt storage portion 24. Each storage portion outlet 32 communicates with each of five die outlets 38 through a corresponding die flow path 36. Each of the five die flow paths 36 was a straight body portion having the same flow path cross-sectional area from the storage portion outlet 32 to the die outlet 38, and an inner diameter of each die flow path 36 was the same as the inner diameter of the introduction portion 36a in Example 1.

FIG. 5B shows a temperature distribution of a melt immediately after the melt is drawn from the die outlet 38 of the die portion 34 using the crystal growth equipment according to Comparative Example 1. T1a, T2a, T3a, and T4a represent a temperature of an indicated region. The temperature is lowest in T1a and gradually increases from T2a to T3a to T4a. For example, the temperature T1a was 1972° C. to 1974° C.; the temperature T2a was 1974° C. to 1976° C.; the temperature T3a was 1976° C. to 1977° C.; and the temperature T4a was 1977° C. or higher.

FIG. 5C shows a concentration distribution of Ce in a cross section of Ce:YAG produced by the crystal growth equipment of Comparative Example 1. In FIG. 5C, C1, C2, C3, and C4 each represent a concentration of Ce in the indicated region. The concentration is lowest in C1 and gradually increases from C2 to C3 to C4. Definitions of the concentrations C1, C2, C3, and C4 are the same as in Example 1.

As shown in FIG. 5C, a size (occupied area) of a region in which the concentration of Ce was uniform with C1 was approximately 30.2% of a total cross-sectional area of the obtained crystal body. As shown in FIG. 5C, the region in which the concentration of Ce is uniform with C1 is located in a central portion of the crystal body, but the area thereof is small and a shape thereof is not circular but distorted. Therefore, an amount and a color of fluorescence generated from a surface of the crystal body vary, which makes it difficult to obtain a uniform light emitting state. In Comparative Example 1, a size (occupied area) of a region in which the concentration of Ce is uniform with C4 is large, but a distribution thereof varies in a circumferential direction, which also causes variations in the amount and color of the fluorescence generated from the surface of the crystal body, so that it is difficult to obtain a uniform light emitting state.

### REFERENCE SIGNS LIST

2 crystal growth equipment
4, 4a, 4b, 4c, 4 crucible
6 refractory furnace
8 outer casing
10 main heater
12 seed crystal holding jig
14 seed crystal
16 after-heater
18, 20, 22 observation window
24 melt storage portion
26 side wall
28 bottom wall
28a lower surface
30 melt
32 storage portion outlet
34, 34a, 34b, 34c, 34 die portion
36, 36 die flow path
36a introduction portion
36a1 narrow portion
36b flow path main body portion
38 die outlet
40, 40a, 40b, 40c divergent portion
41 inward convex portion
41a narrow portion
42 end surface
42a end peripheral surface

What is claimed is:

1. A crucible, comprising:
a melt storage portion for storing a melt of a raw material of a crystal; and
a die portion defining a shape of the crystal, wherein
the die portion includes a die flow path through which the melt is passed from a storage portion outlet provided on a bottom surface of the melt storage portion toward a die outlet provided on an end surface of the die portion, and
the die flow path includes a narrow portion having a flow path cross-sectional area smaller than an opening area of the die outlet.

2. The crucible according to claim 1, wherein
the die flow path includes a divergent portion whose flow path cross-sectional area increases from the narrow portion toward the die outlet along a pulling down direction of the melt.

3. The crucible according to claim 1, wherein
the die flow path includes an introduction portion whose inlet is connected to the storage portion outlet, and a flow path main body portion communicating with the introduction portion, and
an outlet of the flow path main body portion is connected to the die outlet.

4. The crucible according to claim 3, wherein
the introduction portion includes a straight body portion having a substantially constant flow path cross-sectional area along a flow direction of the melt.

5. The crucible according to claim 3, wherein
the introduction portion includes the narrow portion.

6. The crucible according to claim 3, wherein
the flow path main body portion includes the narrow portion.

7. The crucible according to claim 1, wherein
a ratio (S2/S1) of an opening area (S2) of the die outlet to a flow path cross-sectional area (S1) of the narrow portion is 3 to 3000.

8. The crucible according to claim 1, wherein
a flat end peripheral surface substantially perpendicular to a drawing direction of the melt is provided at the end surface of the die portion around the die outlet.

9. The crucible according to claim 8, wherein
a ratio (S2/(S2+S3)) of the opening area (S2) of the die outlet to a sum of the opening area (S2) of the die outlet and an area (S3) of the end peripheral surface is 0.10 to 0.95.

10. The crucible according to claim 1, wherein the crucible is made of iridium, rhenium, molybdenum, tantalum, tungsten, platinum, or an alloy thereof, or carbon.

11. A crystal growth equipment comprising the crucible according to claim 1.
